(19) United States
(12) Patent Application Publication
(10) Pub. No.: US 2024/0044022 A1
(43) Pub. Date: Feb. 8, 2024

(54) Semiconductor Photoelectrode and Method for Manufacturing Same

(71) Applicant: Nippon Telegraph and Telephone Corporation, Tokyo (JP)

(72) Inventors: Yuya Uzumaki, Musashino-shi, Tokyo (JP); Takeshi Komatsu, Musashino-shi, Tokyo (JP); Akihiro Kono, Musashino-shi, Tokyo (JP); Sayumi Sato, Musashino-shi, Tokyo (JP)

(21) Appl. No.: 18/255,968

(22) PCT Filed: Dec. 8, 2020
(86) PCT No.: PCT/JP2020/045598

§ 371 Date: Jun. 5, 2023

(51) Int. Cl. C25B 9/50; C25B 11/02; C25B 11/052; C25B 11/087; C30B 25/02; C23C 14/18; C23C 14/10; C23C 14/58

(52) U.S. Cl. CPC C25B 9/50; C25B 11/02; C25B 11/052; C25B 11/087; C30B 25/02; C23C 14/18; C23C 14/10; C23C 14/5853

(57) ABSTRACT

Provided is a semiconductor photoelectrode that exhibits a catalytic function with light irradiation to cause an oxidation-reduction reaction. The semiconductor photoelectrode includes: a conductive or insulating substrate; a semiconductor thin film disposed on the surface of the substrate; a catalyst layer disposed on the surface of the semiconductor thin film; a light transmission layer disposed in a lattice shape on the surface of the catalyst layer; and a protective layer disposed to cover the rear surface of the substrate and the side surfaces of the substrate and the semiconductor thin film. The semiconductor photoelectrode having another configuration includes a second semiconductor thin film disposed between the semiconductor thin film and the catalyst layer.

### TECHNICAL FIELD

The present invention relates to a semiconductor photoelectrode and a method for manufacturing a semiconductor photoelectrode.

### BACKGROUND ART

A decomposition reaction of water using a photocatalyst is composed of an oxidation reaction of water and a reduction reaction of protons.

Oxidation reaction: 2H₂+4h⁺→O₂+4H⁺

Reduction reaction: 4H⁺+4e⁻→2H₂

When an n-type photocatalyst material is irradiated with light, electrons and holes are generated and separated in the photocatalyst. The holes move to the surface of the photocatalytic material and contribute to the reduction reaction of protons. On the other hand, the electrons move to the reduction electrode and contribute to the reduction reaction of protons. Ideally, such an oxidation-reduction reaction proceeds and a water decomposition reaction occurs.

A conventional water decomposition apparatus has an oxidation tank and a reduction tank connected through a proton exchange membrane, and an aqueous solution and an oxidation electrode are put in the oxidation tank, and the aqueous solution and the reduction electrode are put in the reduction tank. Protons generated in the oxidation tank diffuse into the reduction tank through the proton exchange membrane. The oxidation electrode and the reduction electrode are electrically connected by a conductive wire, and electrons move from the oxidation electrode to the reduction electrode. Light having a wavelength capable of being absorbed by a material constituting the oxidation electrode is emitted from a light source to cause a water decomposition reaction.

### CITATION LIST

### Non Patent Literature

[NPL 1] S. Yotsuhashi, et al., “CO2 Conversion with Light and Water by GaN Photoelectrode,” Japanese Journal of Applied Physics 51 (2012) 02BP07

### SUMMARY OF INVENTION

### Technical Problem

When a gallium nitride thin film grown on, for example, a sapphire substrate is used as the oxidation electrode, oxygen is generated on the gallium nitride surface when the gallium nitride thin film is irradiated with light in an aqueous solution. The process of generating oxygen is mainly composed of (1) adsorption of water to the reaction field, (2) dissociation of 0-H bond, (3) binding of adsorbed oxygen, and (4) separation of oxygen from the reaction field. In order to promote the reaction efficiency, it is necessary to improve the reaction rate of each step of (1) to (4). In order to promote the oxygen generation reaction, for example, NiO is formed as a catalyst material on the surface of the semiconductor, but most of the catalyst material has little contribution to the promotion of the step of (4). There is a problem that the finally generated oxygen does not separate from the surface and covers the reaction field, thus hindering the improvement of efficiency due to catalyst formation.

The present invention has been made in view of the above, and an object of the present invention is to improve a light energy conversion efficiency of a semiconductor photoelectrode which causes an oxidation-reduction reaction with light irradiation.

### Solution to Problem

A semiconductor photoelectrode according to an aspect of the present invention is a semiconductor photoelectrode that exhibits a catalytic function with light irradiation to cause an oxidation-reduction reaction, the semiconductor photoelectrode including: a conductive or insulating substrate; a semiconductor thin film disposed on the surface of the substrate; a catalyst layer disposed on the surface of the semiconductor thin film; a light transmission layer disposed on the surface of the catalyst layer in an uneven pattern; and a protective layer disposed to cover the rear surface of the substrate and the side surfaces of the substrate and the semiconductor thin film.

A method for manufacturing a semiconductor photoelectrode according to another aspect of the present invention is a method for manufacturing a semiconductor photoelectrode that exhibits a catalytic function with light irradiation to cause an oxidation-reduction reaction, the method including: a step of forming a semiconductor thin film on the surface of a conductive or insulating substrate; a step of forming a catalyst layer on the surface of the semiconductor thin film; a step of heat-treating the semiconductor thin film and the catalyst layer; a step of forming a light transmission layer having an uneven pattern on the surface of the catalyst layer; and a step of forming a protective layer so as to cover the rear surface of the substrate and the side surfaces of the substrate and the semiconductor thin film.

### Advantageous Effects of Invention

According to the present invention, it is possible to improve the light energy conversion efficiency of the semiconductor photoelectrode which causes an oxidation-reduction reaction with light irradiation.

### BRIEF DESCRIPTION OF DRAWINGS

FIG. 1 is a cross-sectional view illustrating an example of a configuration of a semiconductor photoelectrode of an embodiment.

FIG. 2 is a top view illustrating an example of the shape of a light transmission layer.

FIG. 3 is a flowchart illustrating an example of a method for manufacturing the semiconductor photoelectrode of FIG. 1.

FIG. 4 is a cross-sectional view illustrating an example of another configuration of the semiconductor photoelectrode of the present embodiment.

FIG. 5 is a flowchart illustrating an example of a method for manufacturing the semiconductor photoelectrode of FIG. 4.

FIG. 6 is a cross-sectional view illustrating an example of a configuration of a semiconductor photoelectrode of a comparative example.

FIG. 7 is a cross-sectional view illustrating an example of a configuration of a semiconductor photoelectrode of a comparative example.

FIG. 8 is a cross-sectional view illustrating an example of a configuration of a semiconductor photoelectrode of a comparative example.

FIG. 9 is a cross-sectional view illustrating an example of a configuration of a semiconductor photoelectrode of a comparative example.

FIG. 10 is a diagram illustrating an example of an apparatus for conducting an oxidation-reduction reaction test.

FIG. 11A is a diagram illustrating a state in which gas is generated on a flat surface.

FIG. 11B is a diagram illustrating a state in which gas is generated and released on an uneven surface.

### DESCRIPTION OF EMBODIMENTS

An embodiment of the present invention will be described below with reference to the drawings. The present invention is not limited to the following embodiment, and may be modified without departing from the spirit of the present invention.

### Configuration of Semiconductor Photoelectrode

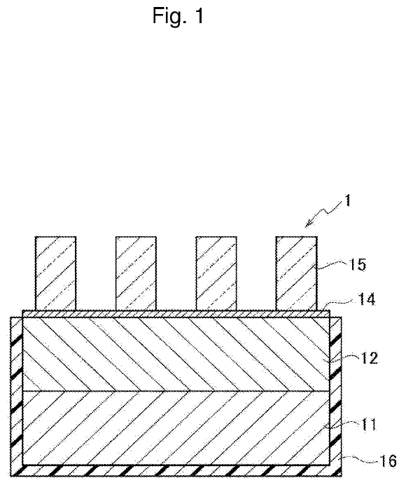

FIG. 1 is a cross-sectional view illustrating an example of a configuration of a semiconductor photoelectrode 1 of an embodiment. The semiconductor photoelectrode 1 exhibits a catalytic function with light irradiation in an aqueous solution to cause an oxidation-reduction reaction. The semiconductor photoelectrode 1 illustrated in FIG. 1 includes an insulating or conductive substrate 11, a semiconductor thin film 12 disposed on the surface of the substrate 11, a catalyst layer 14 disposed on the surface of the semiconductor thin film 12, a light transmission layer 15 disposed in a lattice shape on the surface of the catalyst layer 14, and a protective layer 16 formed to cover the rear surface of the substrate 11 and the side surfaces of the substrate 11 and the semiconductor thin film 12.

As the substrate 11, for example, an insulating or conductive substrate such as a sapphire substrate, a GaN substrate, a glass substrate, or a Si substrate can be used.

The semiconductor thin film 12 has a photocatalytic function of causing a reaction of a target substance with light irradiation. For the semiconductor thin film 12, for example, metal oxides such as gallium nitride (GaN), titanium oxide (TiO₂) , tungsten oxide (WO₃), and gallium oxide (Ga₂O₃), or compound semiconductors such as tantalum nitride (Ta₃N₅) and cadmium sulfide (CdS) can be used.

The catalyst layer 14 uses a material having a promoter function for the semiconductor thin film 12. For the catalyst layer 14, for example, one or more metals selected from Ni, Co, Cu, W, Ta, Pd, Ru, Fe, Zn, and Nb, or oxides of these metals can be used. The film thickness of the catalyst layer 14 is preferably 1 nm to 10 nm, particularly 1 nm to 3 nm at which sufficient light is able to be transmitted. The catalyst layer 14 may entirely cover the surface exposed part of the semiconductor thin film 12 or may cover only a part thereof.

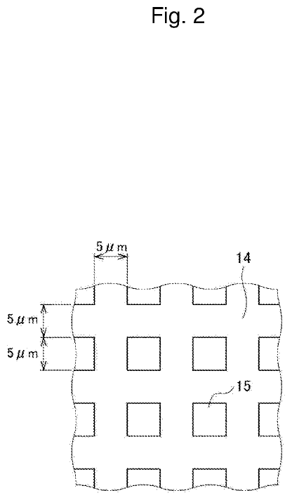

The light transmission layer 15 is an uneven structure disposed on the surface of the catalyst layer 14. In the present example, as illustrated in FIG. 2, the light transmission layer 15 is formed in a lattice shape with 5 μm squares and a pitch of 10 μm. In order to obtain a desorption effect in view of a typical bubble size of the generated gas, it is preferable that the pitch be 20 μm or less (the lattice interval be 10 μm or less). The film thickness of the light transmission layer 15 is preferably within a range (5 to 50 nm) at which the transmission of light is not hindered and a continuous film can be formed. When the film thickness of the light transmission layer 15 is 5 nm or less, the denseness and uniformity of the layer become insufficient, and the semiconductor thin film 12 is deteriorated by the contact of the aqueous solution with the semiconductor thin film 12. On the other hand, when the film thickness of the light transmission layer 15 is 50 nm or more, light having a wavelength absorbed by the semiconductor in the lower layer is not sufficiently transmitted. The shape of the uneven structure of the light transmission layer 15 is not limited to a lattice, and the width and depth of the recessed part may be any width and depth that can obtain the effect of releasing the bubbles of the generated gas.

For example, SiO₂ can be used for the light transmission layer 15. The light transmission layer 15 may be made of a material that transmits light having a wavelength absorbed by the semiconductor in the lower layer.

The protective layer 16 is used to prevent deterioration due to contact between the substrate 11 and the aqueous solution of the semiconductor thin film 12. For the protective layer 16, an insulating material such as epoxy resin that does not react with the aqueous solution, the substrate 11, and the semiconductor thin film 12 is used.

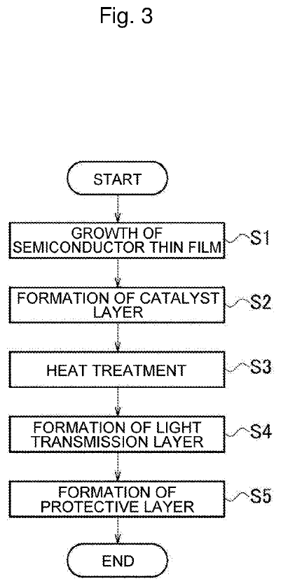

Subsequently, a method for manufacturing the semiconductor photoelectrode 1 of FIG. 1 will be described with reference to FIG. 3.

In step S1, a semiconductor thin film 12 is grown on the substrate 11.

In step S2, the catalyst layer 14 is formed on the surface of the semiconductor thin film 12. The catalyst layer 13 may be formed to cover the entire surface of the semiconductor thin film 12, or the catalyst layer 13 may be formed to cover only a part of the surface of the semiconductor thin film 12.

In step S3, a sample in which the semiconductor thin film 12 and the catalyst layer 13 are formed on the substrate 11 is heat-treated. The heat treatment may be performed on a hot plate or in an electric furnace.

In step S4, the light transmission layer 15 is vacuum-deposited by using a mask so that the light transmission layer 15 has a predetermined shape pattern.

In step S5, the protective layer 16 is formed to cover the rear surface and the side surface of the substrate 11 and the side surface of the semiconductor thin film 12.

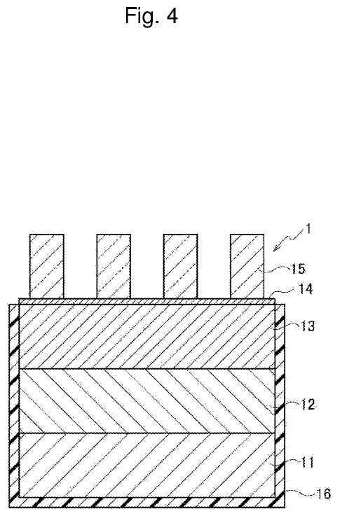

Subsequently, another configuration of the semiconductor photoelectrode 1 of the present embodiment will be described with reference to FIG. 4.

The semiconductor photoelectrode 1 illustrated in FIG. 4 includes an insulating or conductive substrate 11, a semiconductor thin film 12 disposed on the surface of the substrate 11, a second semiconductor thin film 13 disposed on the surface of the semiconductor thin film 12, a catalyst layer 14 disposed on the surface of the second semiconductor thin film 13, a light transmission layer 15 disposed in a lattice shape on the surface of the catalyst layer 14, and a protective layer 16 formed to cover the rear surface of the substrate 11 and the side surfaces of the substrate 11 and the semiconductor thin films 12 and 13. The difference from the semiconductor photoelectrode 1 of the first embodiment is that the second semiconductor thin film 13 is disposed between the semiconductor thin film 12 and the catalyst layer 14.

For the second semiconductor thin film 13, for example, compound semiconductors such as indium gallium nitride (InGaN) and aluminum gallium nitride (AlGaN) can be used.

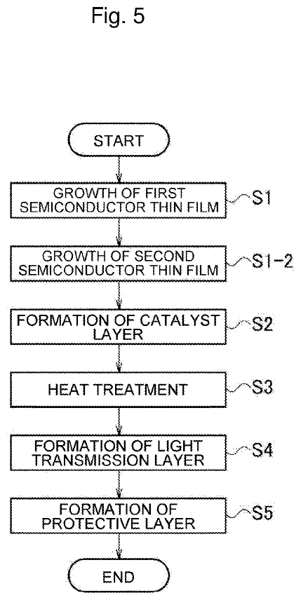

Subsequently, a method for manufacturing the semiconductor photoelectrode 1 of FIG. 1 will be described with reference to FIG. 5.

In step S1, the semiconductor thin film 12 is grown on the substrate 11, and in step S1-2, the second semiconductor thin film 13 is grown on the semiconductor thin film 12.

Thereafter, the catalyst layer 14, the light transmission layer 15, and the protective layer 16 are formed in the same manner as in steps S2 to S5 in FIG. 2.

### Example of Semiconductor Photoelectrode

Semiconductor photoelectrodes of Examples 1 to 6 were prepared in which the configuration of the semiconductor photoelectrode, the material of the substrate, and the material of the second semiconductor thin film were changed, and an oxidation-reduction reaction test to be described later was performed. The semiconductor photoelectrodes of Examples 1 to 6 will be described below.

### EXAMPLE 1

A semiconductor photoelectrode of Example 1 is the semiconductor photoelectrode having the configuration illustrated in FIG. 1. A sapphire substrate was used.

In step S1, an n-GaN thin film was epitaxially grown on the sapphire substrate by metal organic chemical vapor deposition (MOCVD) to form a semiconductor thin film as a light absorption layer (a layer that absorbs light and generates electrons and holes). Ammonia gas and trimethyl gallium were used as the growth raw material. Hydrogen was used as the carrier gas sent into the growth furnace. The film thickness of the n-GaN thin film was set to 2 μm, which is sufficient for light absorption. The carrier density was 3×10¹⁸ cm⁻³.

In step S2, Ni was deposited on the surface of the n-GaN thin film by vapor deposition in a thickness of 1 nm.

In step S3, the sample was heat-treated in air at 300° C. for 1 hour to form an NiO layer. The film thickness of NiO was 2 nm when the sample cross section was TEM-observed.

In step S4, SiO₂ with a film thickness of about 50 nm was vacuum-deposited on the surface of the NiO layer by using a mask so as to form a lattice pattern of 5 μm square and pitch 10 μm illustrated in FIG. 2. From the shape of the pattern, the NiO layer had a surface area of about 0.75 cm² and the SiO₂ layer had a surface area of about 0.25 cm². The surface area of the sample is about 1 cm².

In step S5, a protective layer was formed by using an epoxy resin so as to cover the rear surface of the sapphire substrate (the surface on which the n-GaN thin film was not formed) and the side surfaces of the sapphire substrate and the n-GaN thin film.

The semiconductor photoelectrode of Example 1 was obtained through the above steps. In the oxidation-reduction reaction test to be described later, the n-GaN surface was removed, a conductive wire was connected to a part of the n-GaN surface, and soldered using In, the indium surface was covered with an epoxy resin so as not to be exposed, and the resulting electrode was installed as an oxidation electrode.

### EXAMPLE 2

A semiconductor photoelectrode of Example 2 is the semiconductor photoelectrode having the configuration illustrated in FIG. 4. A sapphire substrate was used, and indium gallium nitride was used as a material of the second semiconductor thin film 13.

In step S1, an n-GaN thin film was epitaxially grown on the sapphire substrate by MOCVD. Ammonia gas and trimethyl gallium were used as the growth raw material. Hydrogen was used as the carrier gas sent into the growth furnace. The film thickness of the n-GaN thin film was set to 2 μm. The carrier density was 3×10¹⁸ cm⁻³.

In step S1-2, an indium gallium nitride (InGaN) thin film having an indium composition ratio of 5% was grown on the n-GaN thin film. Ammonia gas, trimethyl gallium, and trimethyl indium were used as the growth raw material. Hydrogen was used as the carrier gas sent into the growth furnace. The film thickness of the InGaN thin film was set to 100 nm, which is sufficient for light absorption.

In step S2, Ni was deposited on the surface of the InGaN thin film by vapor deposition in a film thickness of 1 nm.

In step S3, the sample was heat-treated in air at 300° C. for 1 hour to form an NiO layer. The film thickness of NiO was 2 nm when the sample cross section was TEM-observed.

In step S4, SiO₂ with a film thickness of about 50 nm was vacuum-deposited on the surface of the NiO layer by using a mask so as to form a lattice pattern of 5 μm square and pitch 10 μm illustrated in FIG. 2.

In step S5, a protective layer was formed by using an epoxy resin so as to cover the rear surface of the sapphire substrate and the side surfaces of the sapphire substrate, the n-GaN thin film, and the InGaN thin film.

The semiconductor photoelectrode of Example 2 was obtained through the above steps. In the oxidation-reduction reaction test to be described later, the InGaN surface was removed, n-GaN was exposed, a conductive wire was connected to a part of the n-GaN surface, and soldered using In, the indium surface was covered with an epoxy resin so as not to be exposed, and the resulting electrode was installed as an oxidation electrode.

### EXAMPLE 3

A semiconductor photoelectrode of Example 3 is the semiconductor photoelectrode having the configuration illustrated in FIG. 4. A sapphire substrate was used, and aluminum gallium nitride was used as a material of the second semiconductor thin film 13.

In step S1, an n-GaN thin film was epitaxially grown on the sapphire substrate by MOCVD. Ammonia gas and trimethyl gallium were used as the growth raw material. Hydrogen was used as the carrier gas sent into the growth furnace. The film thickness of the n-GaN thin film was set to 2 μm. The carrier density was 3×10¹⁸ cm⁻³.

In step S1-2, an aluminum gallium nitride (AlGaN) thin film having an aluminum composition ratio of 10% was grown on the n-GaN thin film. Ammonia gas, trimethyl gallium, and trimethyl aluminum were used as the growth raw material. Hydrogen was used as the carrier gas sent into the growth furnace. The film thickness of the AlGaN thin film was set to 100 nm, which is sufficient for light absorption.

The steps after step S2 were performed in the same manner as in Example 2.

### EXAMPLE 4

A semiconductor photoelectrode of Example 4 is the semiconductor photoelectrode having the configuration illustrated in FIG. 1. This example differs from Example 1 in that an n-GaN substrate is used.

In step S1, an n-GaN thin film was epitaxially grown on the n-GaN substrate by MOCVD. Ammonia gas and trimethyl gallium were used as the growth raw material. Hydrogen was used as the carrier gas sent into the growth furnace. The film thickness of the n-GaN thin film was set to 2 μm. The carrier density was 3×10¹⁸ cm⁻³.

The steps after step S2 were performed in the same manner as in Example 1.

### EXAMPLE 5

A semiconductor photoelectrode of Example 5 is the semiconductor photoelectrode having the configuration illustrated in FIG. 4. This example differs from Example 2 in that an n-GaN substrate is used.

In step S1, an n-GaN thin film was epitaxially grown on the n-GaN substrate by MOCVD. Ammonia gas and trimethyl gallium were used as the growth raw material. Hydrogen was used as the carrier gas sent into the growth furnace. The film thickness of the n-GaN thin film was set to 2 82 m. The carrier density was 3×10¹⁸ cm⁻³.

The steps after step S1-2 were performed in the same manner as in Example 2.

### EXAMPLE 6

A semiconductor photoelectrode of Example 6 is the semiconductor photoelectrode having the configuration illustrated in FIG. 4. This example differs from Example 2 in that an n-GaN substrate is used.

In step S1, an n-GaN thin film was epitaxially grown on the n-GaN substrate by MOCVD. Ammonia gas and trimethyl gallium were used as the growth raw material. Hydrogen was used as the carrier gas sent into the growth furnace. The film thickness of the n-GaN thin film was set to 2 μm. The carrier density was 3×10¹⁸ cm⁻³.

The steps after step S1-2 were performed in the same manner as in Example 3.

Subsequently, Comparative Examples 1 to 4 will be described.

### Comparative Example 1

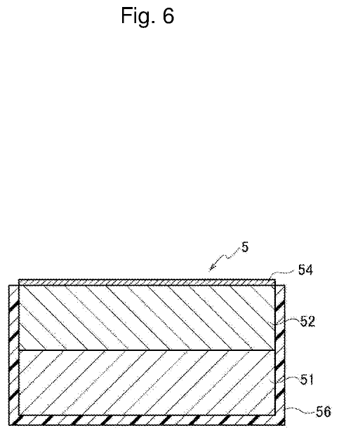

As illustrated in FIG. 6, Comparative Example 1 has a configuration in which the light transmission layer is not formed on the semiconductor photoelectrode of Example 1. A semiconductor photoelectrode 5 of Comparative Example 1 illustrated in FIG. 6 includes a substrate 51, a semiconductor thin film 52, a catalyst layer 54, and a protective layer 56.

The semiconductor photoelectrode of Comparative Example 1 does not perform step S4 in Example 1. In Comparative Example 1, the surface area of the NiO layer (the semiconductor thin film 52) was set to about 0.75 cm² and the area of the reaction field was the same as in Example 1. Other points are the same as in Example 1.

### Comparative Example 2

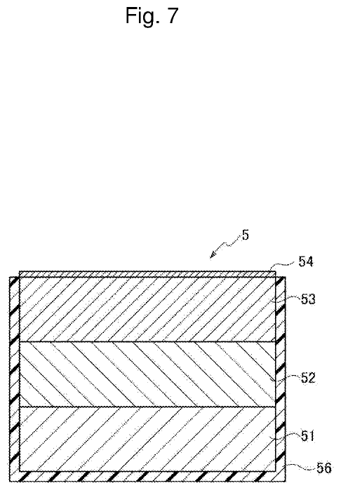

As illustrated in FIG. 7, Comparative Example 2 has a configuration in which the light transmission layer is not formed on the semiconductor photoelectrode of Example 2. A semiconductor photoelectrode 5 of Comparative Example 2 illustrated in FIG. 7 includes a substrate 51, a semiconductor thin film 52, a second semiconductor thin film 53, a catalyst layer 54, and a protective layer 56.

The semiconductor photoelectrode of Comparative Example 2 does not perform step S4 in Example 2. In Comparative Example 1, the surface area of the NiO layer (the semiconductor thin film 52) was set to about 0.75 cm² and the area of the reaction field was the same as in Example 2. Other points are the same as in Example 2.

### Comparative Example 3

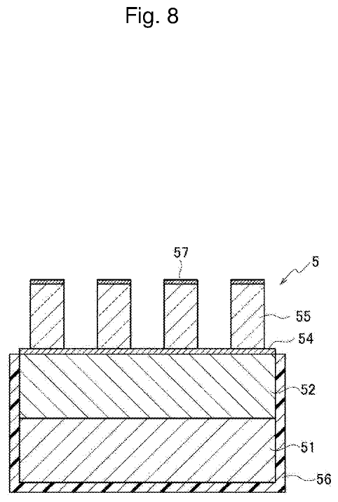

As illustrated in FIG. 8, Comparative Example 3 has a configuration in which a light shielding layer is formed on the SiO₂ layer of the semiconductor photoelectrode of Example 1. A semiconductor photoelectrode 5 of Comparative Example 3 illustrated in FIG. 8 includes a substrate 51, a semiconductor thin film 52, a catalyst layer 54, a light transmission layer 55, and a protective layer 56, and further includes a light shielding layer 57 on the light shielding layer 55.

In the semiconductor photoelectrode of Comparative Example 3, after forming an SiO₂ layer of 40 nm in step S4 of Example 1, Ni was vapor-deposited on the SiO₂ layer to a thickness of 10 nm by using the same mask. Other points are the same as in Example 1.

### Comparative Example 4

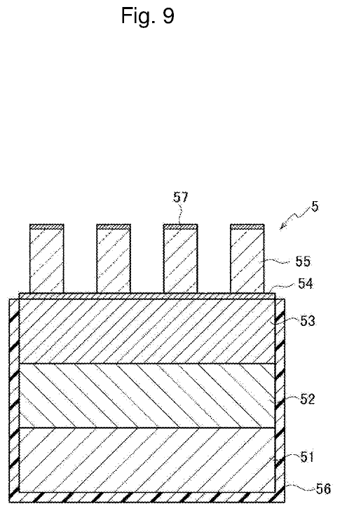

As illustrated in FIG. 9, Comparative Example 4 has a configuration in which a light shielding layer is formed on the SiO₂ layer of the semiconductor photoelectrode of Example 2. A semiconductor photoelectrode 5 of Comparative Example 4 illustrated in FIG. 9 includes a substrate 51, a semiconductor thin film 52, a second semiconductor thin film 53, a catalyst layer 54, a light transmission layer 55, and a protective layer 56, and further includes a light shielding layer 57 on the light shielding layer 55.

In the semiconductor photoelectrode of Comparative Example 4, after forming an SiO₂ layer of 40 nm in step S4 of Example 2, Ni was vapor-deposited on the SiO₂ layer to a thickness of 10 nm by using the same mask. Other points are the same as in Example 2.

### Oxidation-Reduction Reaction Test

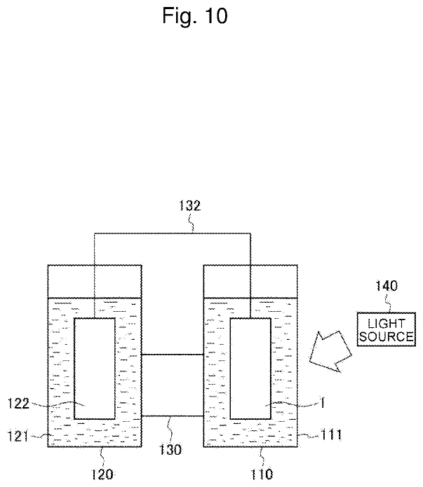

An oxidation-reduction reaction test was conducted using the apparatus illustrated in FIG. 10 for Examples 1 to 6 and Comparative Examples 1 to 4.

The apparatus illustrated in FIG. 10 includes an oxidation tank 110 and a reduction tank 120. An aqueous solution 111 is put in the oxidation tank 110, and the semiconductor photoelectrode 1 of Examples 1 to 4 or the semiconductor photoelectrode 5 of Comparative Examples 1 to 4 as the oxidation electrode 1 is put in the aqueous solution 111. An aqueous solution 121 is put in the reduction tank 120, and a reduction electrode 122 is put in the aqueous solution 121.

A 1 mol/l sodium hydroxide aqueous solution was used as the aqueous solution 111 in the oxidation tank 110. As the aqueous solution 111, a potassium hydroxide aqueous solution or hydrochloric acid may be used. When the oxidation electrode 1 is composed of gallium nitride, an alkaline aqueous solution is preferable.

A 0.5 mol/l potassium hydrogen carbonate aqueous solution was used as the aqueous solution 121 in the reduction tank 120. As the aqueous solution 121, a sodium bicarbonate aqueous solution, a potassium chloride aqueous solution, or a sodium chloride aqueous solution may be used.

As the reduction electrode 122, Platinum (manufactured by The Nilaco Corporation) was used. The reduction electrode 122 may be a metal or a metal compound. As the reduction electrode 122, for example, nickel, iron, gold, copper, indium, or titanium may be used.

The oxidation tank 110 and the reduction tank 120 are connected through a proton film 130. Protons generated in the oxidation tank 110 diffuse into the reduction tank 120 through the proton film 130. Nafion (registered trademark) was used for the proton film 130. Nafion is a perfluorocarbon material composed of a hydrophobic Teflon skeleton composed of carbon-fluorine and a perfluoro side chain having a sulfonic acid group.

The oxidation electrode 1 and the reduction electrode 122 are electrically connected by a conductive wire 132, and electrons move from the oxidation electrode 1 to the reduction electrode 122.

A 300 W high pressure xenon lamp (illuminance 5 mW/cm²) was used as a light source 140. The light source 140 may be able to emit light having a wavelength that can be absorbed by a material constituting a semiconductor photoelectrode installed as an oxidation electrode. For example, in an oxidation electrode composed of gallium nitride, the wavelength that can be absorbed is 365 nm or less. As the light source 140, light sources such as a xenon lamp, a mercury lamp, a halogen lamp, a pseudo sunlight source, or sunlight may be used, or these light sources may be combined.

In the oxidation-reduction reaction test, nitrogen gas was flowed at 10 ml/min in each reaction tank, and the light irradiation area of the sample was set to 1 cm² (the surface area was 1.5 cm² in the case of Example 1), and the aqueous solutions 111 and 121 were stirred at the center position of the bottom of each reaction tank at a rotation speed of 250 rpm using an agitator and a stirrer.

After the reaction tank was sufficiently replaced with nitrogen gas, the light source 140 was fixed to face the surface of the semiconductor photoelectrode to be tested on which NiO was formed, and the semiconductor photoelectrode was irradiated uniformly with light.

After 10 hours of light irradiation, the gas in each reaction tank was collected and the reaction product was analyzed by a gas chromatograph. As a result, it was confirmed that oxygen was generated in the oxidation tank 110 and hydrogen was generated in the reduction tank 120. By changing the metal of the reduction electrode to, for example, Ni, Fe, Au, Pt, Ag, Cu, In, Ti, Co, or Ru, or by changing the atmosphere in the cell, it is possible to produce a carbon compound by the reduction reaction of carbon dioxide and to produce ammonia by the reduction reaction of nitrogen.

### Test Results

Table 1 shows the amount of oxygen/hydrogen gas generated with respect to the light irradiation time in Examples 1 to 6 and Comparative Examples 1 to 4. The amount of each gas generated was normalized by the surface area of the semiconductor photoelectrode.

TABLE 1

| | | | | | | | Amount of gas generated in | |
|---|---|---|---|---|---|---|---|---|
| | | | Second | Light absorption | Reaction | Ligh transmission | cell/μmol · h⁻¹ | |
| | | Semiconductor | semiconductor | area | field area | layer area | After 10 hours of light irradiation | |
| Sample | Substrate | thin film | thin film | (cm¹) | (cm¹) | (cm²) | Oxygen | Hydrogen |
| Example 1 | Sapphire | n-GaN | None | 1 | 0.75 | 0.25 | 12 | 24 |
| Example 2 | Sapphire | n-GaN | InGaN | 1 | 0.75 | 0.25 | 40 | 80 |
| Example 3 | Sapphire | n-GaN | AlGaN | 1 | 0.75 | 0.25 | 26 | 52 |
| Example 4 | n-GaN | n-GaN | None | 1 | 0.75 | 0.25 | 11 | 24 |
| Example 5 | n-GaN | n-GaN | InGaN | 1 | 0.75 | 0.25 | 41 | 82 |
| Example 6 | n-GaN | n-GaN | AlGaN | 1 | 0.75 | 0.25 | 27 | 55 |
| Comparative | Sapphire | n-GaN | None | 0.75 | 0.75 | 0 | 4 | 8 |
| Example 1 | | | | | | | | |
| Comparative | Sapphire | n-GaN | InGaN | 0.75 | 0.75 | 0 | 19 | 39 |
| Example 2 | | | | | | | | |
| Comparative | Sapphire | n-GaN | None | 0.75 | 0.75 | 0.25 | 9 | 18 |
| Example 3 | | | | | | | | |
| Comparative | Sapphire | n-GaN | InGaN | 0.75 | 0.75 | 0.25 | 32 | 64 |
| Example 4 | | | | | | | | |

It was found that all Examples 1 to 6 and Comparative Examples 1 to 4 generated oxygen and hydrogen when irradiated with light.

Example 2 generated a larger amount of gas than Example 1. This is because the InGaN thin film of the light absorption layer has a wider wavelength region that can be absorbed than the GaN thin film. Example 3 also generated a larger amount of gas than Example 1. This is because AlGaN is used for the light absorption layer to form an AlGaN/GaN heterostructure, a large electric field is generated in AlGaN, and charge separation is promoted. The same applies to the comparison between Examples 4 and 5 and between Examples 4 and 6.

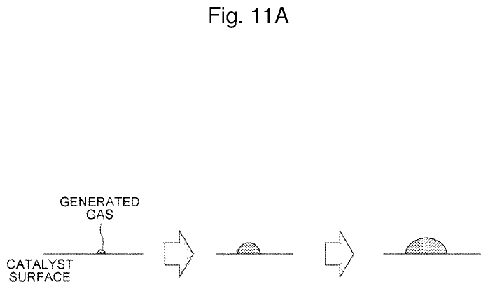

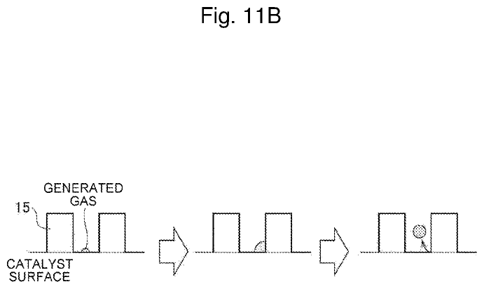

Although the area of the reaction field is the same, the amount of gas generation in Example 1 was larger than that in Comparative Example 1. As illustrated in FIGS. 11A and 11B, it is considered that Example 1 is provided with the light transmission layer 15 to reduce surface tension and promote the separation of the generated gas rather than the flat surface. The same applies to the comparison between Example 2 and Comparative Example 2.

However, in Example 1 and Comparative Example 1, it is considered that the light absorption area of Example 1 is larger, and the generation amount may have increased due to the influence of the light absorption area. Therefore, Comparative Example 3 and Comparative Example 1 are compared. In Comparative Example 3, the light shielding layer 57 shields the light of the light transmission layer 55, and thus the light absorption area and the reaction field area are made equal to those of Comparative Example 1. Comparative Example 3 generated a larger amount of gas than Comparative Example 1. As a result, it is considered that the surface of the semiconductor photoelectrode is made uneven to lower the surface tension, and the separation of the generated gas is promoted, thereby increasing the amount of the generated gas. The same applies to the comparison between Comparative Example 2 and Comparative Example 4.

The separation of the generated gas depends on the surface tension of the surface of the semiconductor photoelectrode. Since the surface tension can be reduced by the structure of the surface of the semiconductor photoelectrode, by making the surface structure of the semiconductor photoelectrode uneven and promoting the separation of the generated gas, the efficiency of the amount of hydrogen and oxygen generated by the water decomposition reaction (light energy conversion efficiency) could be improved.

As described above, the semiconductor photoelectrode 1 of the present embodiment includes the conductive or insulating substrate 11, the semiconductor thin film 12 disposed on the surface of the substrate 11, the catalyst layer 14 disposed on the surface of the semiconductor thin film 12, the light transmission layer 15 disposed in a lattice shape on the surface of the catalyst layer 14, and the protective layer 16 disposed to cover the rear surface of the substrate 11 and the side surfaces of the substrate 11 and the semiconductor thin film 12. By providing the light transmission layer 15 of the uneven pattern on the surface of the semiconductor photoelectrode 1, the separation of the generated gas from the surface of the semiconductor photoelectrode 1 is promoted, and thus the generation amount of the gas by the oxidation-reduction reaction can be increased, that is, the light energy conversion efficiency can be improved.

### REFERENCE SIGNS LIST

1 Semiconductor photoelectrode
11 Substrate
12, 13 Semiconductor thin film
14 Catalyst layer
15 Light transmission layer
16 Protective layer

1. A semiconductor photoelectrode that exhibits a catalytic function with light irradiation to cause an oxidation-reduction reaction, the semiconductor photoelectrode comprising:
a conductive or insulating substrate;
a semiconductor thin film disposed on a surface of the substrate;
a catalyst layer disposed on a surface of the semiconductor thin film;
a light transmission layer disposed on a surface of the catalyst layer in an uneven pattern; and
a protective layer disposed to cover a rear surface of the substrate and side surfaces of the substrate and the semiconductor thin film.

2. The semiconductor photoelectrode according to claim 1, further comprising:
a second semiconductor thin film disposed between the semiconductor thin film and the catalyst layer.

3. The semiconductor photoelectrode according to claim 1,
wherein the semiconductor thin film is an n-type semiconductor.

4. The semiconductor photoelectrode according to claim 1,
wherein the uneven pattern is a lattice pattern.

5. A method for manufacturing a semiconductor photoelectrode that exhibits a catalytic function with light irradiation to cause an oxidation-reduction reaction, the method comprising:
a step of forming a semiconductor thin film on a surface of a conductive or insulating substrate;
a step of forming a catalyst layer on a surface of the semiconductor thin film;
a step of heat-treating the semiconductor thin film and the catalyst layer;
a step of forming a light transmission layer having an uneven pattern on a surface of the catalyst layer; and
a step of forming a protective layer so as to cover a rear surface of the substrate and side surfaces of the substrate and the semiconductor thin film.

6. The method for manufacturing a semiconductor photoelectrode according to claim 5, further comprising:
a step of forming a second semiconductor thin film on the surface of the semiconductor thin film after the step of forming the semiconductor thin film,
wherein the step of forming the catalyst layer includes forming the catalyst layer on a surface of the second semiconductor thin film.

7. The semiconductor photoelectrode according to claim 2,
wherein the semiconductor thin film is an n-type semiconductor.

8. The semiconductor photoelectrode according to claim 2,
wherein the uneven pattern is a lattice pattern.

9. The semiconductor photoelectrode according to claim 3,
wherein the uneven pattern is a lattice pattern.
